(19) United States
(12) Patent Application Publication
(10) Pub. No.: US 2023/0335609 A1
(43) Pub. Date: Oct. 19, 2023

(54) TRANSISTOR STRUCTURE AND MANUFACTURING METHOD THEREOF

(71) Applicant: United Microelectronics Corp., Hsinchu (TW)

(72) Inventors: Ming-Hua Tsai, Tainan City (TW); Wei Hsuan Chang, Tainan City (TW); Chin-Chia Kuo, Tainan City (TW)

(73) Assignee: United Microelectronics Corp., Hsinchu (TW)

(21) Appl. No.: 17/736,071

(22) Filed: May 3, 2022

(30) Foreign Application Priority Data
Apr. 13, 2022 (CN) 202210386850.4

(51) Int. Cl. H01L 29/423; H01L 29/40; H01L 21/8234

(52) U.S. Cl. CPC H01L 29/42368; H01L 29/401; H01L 21/823462; H01L 27/088

(57) ABSTRACT

The invention provides a transistor structure and a manufacturing method thereof. The transistor structure includes a substrate, a first gate, a second gate, a first gate dielectric layer, and a second gate dielectric layer. The first gate and the second gate are located on the substrate. The first gate dielectric layer is located between the first gate and the substrate. The first gate dielectric layer has a single thickness. The second gate dielectric layer is located between the second gate and the substrate. The second gate dielectric layer has a plurality of thicknesses. A maximum thickness of the first gate dielectric layer is the same as a maximum thickness of the second gate dielectric layer. The transistor structure may reduce process complexity.

### CROSS-REFERENCE TO RELATED APPLICATION

This application claims the priority benefit of China patent application serial no. 202210386850.4, filed on Apr. 13, 2022. The entirety of the above-mentioned patent application is hereby incorporated by reference herein and made a part of this specification.

### BACKGROUND OF THE INVENTION

### Field of the Invention

The invention relates to a semiconductor structure and a manufacturing method thereof, in particular to a transistor structure and a manufacturing method thereof.

### Description of Related Art

Currently, in order to make transistors have different electrical properties, the thicknesses of gate dielectric layers of a plurality of transistors are designed to be different from each other. However, the current process for manufacturing a plurality of gate dielectric layers with different thicknesses is complicated, so how to reduce process complexity is an ongoing goal.

### SUMMARY OF THE INVENTION

The invention provides a transistor structure and a manufacturing method thereof that may reduce process complexity.

The invention provides a transistor structure including a substrate, a first gate, a second gate, a first gate dielectric layer, and a second gate dielectric layer. The first gate and the second gate are located on the substrate. The first gate dielectric layer is located between the first gate and the substrate. The first gate dielectric layer has a single thickness. The second gate dielectric layer is located between the second gate and the substrate. The second gate dielectric layer has a plurality of thicknesses. A maximum thickness of the first gate dielectric layer is the same as a maximum thickness of the second gate dielectric layer.

According to an embodiment of the invention, in the transistor structure, the second gate dielectric layer may include at least one protruding portion.

According to an embodiment of the invention, in the transistor structure, the protruding portion may have a top surface and a sidewall. The sidewall may be connected to the top surface.

According to an embodiment of the invention, in the transistor structure, the sidewall may be not perpendicular to the top surface.

According to an embodiment of the invention, in the transistor structure, the sidewall may be perpendicular to the top surface.

According to an embodiment of the invention, the transistor structure may further include a third gate and a third gate dielectric layer. The third gate is located on the substrate. The third gate dielectric layer is located between the third gate and the substrate. The third gate dielectric layer may have a single thickness.

According to an embodiment of the invention, in the transistor structure, a maximum thickness of the second gate dielectric layer may be greater than a maximum thickness of the third gate dielectric layer.

According to an embodiment of the invention, in the transistor structure, a minimum thickness of the second gate dielectric layer may be equal to a maximum thickness of the third gate dielectric layer.

According to an embodiment of the invention, in the transistor structure, the first gate and the second gate may be separated from each other.

According to an embodiment of the invention, in the transistor structure, the first gate dielectric layer and the second gate dielectric layer may be separated from each other.

The invention provides a manufacturing method of a transistor structure, including the following steps. A substrate is provided. A gate dielectric material layer is formed on the substrate. A first patterned photoresist layer is formed on the gate dielectric material layer. The first patterned photoresist layer exposes a portion of the gate dielectric material layer. A height of the portion of the gate dielectric material layer exposed by the first patterned photoresist layer is reduced. The first patterned photoresist layer is removed. A first gate and a second gate are formed on the gate dielectric material layer. The gate dielectric material layer is patterned to form a first gate dielectric layer located between the first gate and the substrate and a second gate dielectric layer located between the second gate and the substrate. The first gate dielectric layer has a single thickness. The second gate dielectric layer has a plurality of thicknesses.

According to an embodiment of the invention, in the manufacturing method of the transistor structure, a maximum thickness of the first gate dielectric layer may be equal to a maximum thickness of the second gate dielectric layer.

According to an embodiment of the invention, in the manufacturing method of the transistor structure, the following steps may be further included. A third gate is formed on the gate dielectric material layer.

According to an embodiment of the invention, in the manufacturing method of the transistor structure, patterning the gate dielectric material layer may further include forming a third gate dielectric layer located between the third gate and the substrate.

The third gate dielectric layer may have a single thickness.

According to an embodiment of the invention, in the manufacturing method of the transistor structure, a maximum thickness of the second gate dielectric layer may be greater than a maximum thickness of the third gate dielectric layer.

According to an embodiment of the invention, in the manufacturing method of the transistor structure, a minimum thickness of the second gate dielectric layer may be equal to a maximum thickness of the third gate dielectric layer.

According to an embodiment of the invention, in the manufacturing method of the transistor structure, the following steps may be further included. After the first patterned photoresist layer is removed, a second patterned photoresist layer is formed on the gate dielectric material layer. The second patterned photoresist layer exposes a portion of the gate dielectric material layer. A height of the portion of the gate dielectric material layer exposed by the second patterned photoresist layer is reduced.

According to an embodiment of the invention, in the manufacturing method of the transistor structure, a method of reducing the height of the portion of the gate dielectric material layer exposed by the first patterned photoresist layer is, for example, an etching method.

According to an embodiment of the invention, in the manufacturing method of the transistor structure, the etching method may be a wet etching method.

According to an embodiment of the invention, in the manufacturing method of the transistor structure, the etching method may be a dry etching method.

Based on the above, in the transistor structure provided by the invention, the first gate dielectric layer has a single thickness, the second gate dielectric layer has a plurality of thicknesses, and the maximum thickness of the first gate dielectric layer is the same as the maximum thickness of the second gate dielectric layer. Therefore, the equivalent oxide thickness (EOT) of the first gate dielectric layer may be greater than the EOT of the second gate dielectric layer. In addition, since the second gate dielectric layer has a plurality of thicknesses, the EOT of the second gate dielectric layer may be flexibly adjusted via the plurality of thicknesses of the second gate dielectric layer. Moreover, the maximum thickness of the first gate dielectric layer is the same as the maximum thickness of the second gate dielectric layer. Therefore, the first gate dielectric layer and the second gate dielectric layer may be formed from the same gate dielectric material layer, thereby reducing process complexity.

Moreover, in the manufacturing method of the transistor structure provided by the invention, the height of the portion of the gate dielectric material layer exposed by the first patterned photoresist layer is reduced first, and then the gate dielectric material layer is patterned to form the first gate dielectric layer having a single thickness and the second gate dielectric layer having a plurality of thicknesses. Since the first gate dielectric layer and the second gate dielectric layer are formed of the same gate dielectric material layer, process complexity may be reduced. Moreover, the first patterned photoresist layer may be integrated with the patterned photoresist layers used to manufacture other semiconductor devices (e.g., low-voltage transistor devices), thereby reducing the number of photomasks needed for the manufacturing process. Moreover, the first gate dielectric layer has a single thickness, and the second gate dielectric layer has a plurality of thicknesses, so the first gate dielectric layer and the second gate dielectric layer may have different EOTs. In addition, since the second gate dielectric layer has a plurality of thicknesses, the EOT of the second gate dielectric layer may be flexibly adjusted via the plurality of thicknesses of the second gate dielectric layer.

In order to make the above features and advantages of the invention better understood, embodiments are specifically provided below with reference to figures for detailed description as follows.

### BRIEF DESCRIPTION OF THE DRAWINGS

FIG. 1A to FIG. 1D are cross-sectional views of the manufacturing process of a transistor structure according to some embodiments of the invention.

FIG. 2A to FIG. 2C are cross-sectional views of the manufacturing process of a transistor structure according to some other embodiments of the invention.

FIG. 3A to FIG. 3F are cross-sectional views of the manufacturing process of a transistor structure according to some other embodiments of the invention.

### DESCRIPTION OF THE EMBODIMENTS

The following examples will be described in detail with reference to the accompanying drawings, but the provided examples are not intended to limit the scope of the invention. In order to facilitate understanding, the same components will be described with the same reference numerals in the following description. In addition, the drawings are for illustrative purposes only, and are not drawn in full scale. In fact, the dimensions of the various features may be arbitrarily increased or decreased for clarity of discussion.

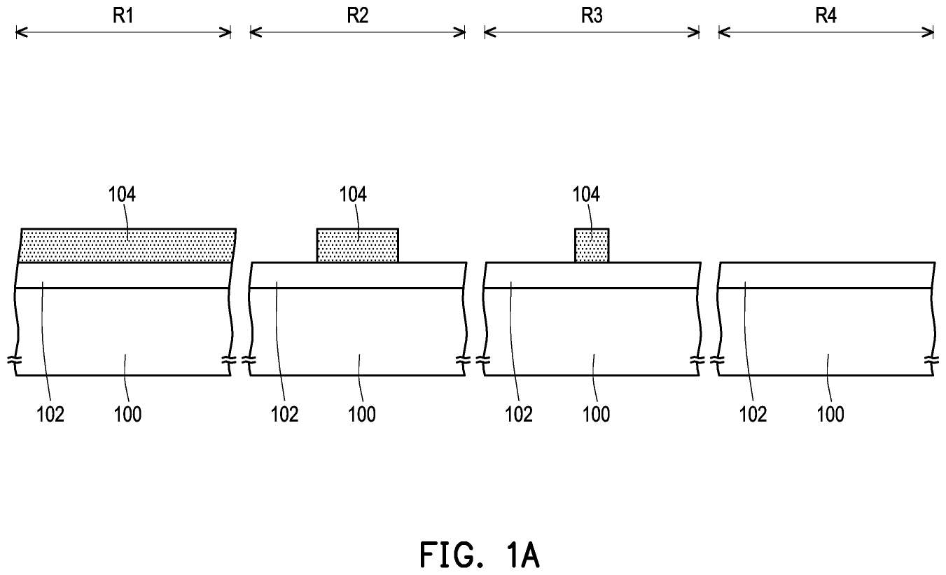

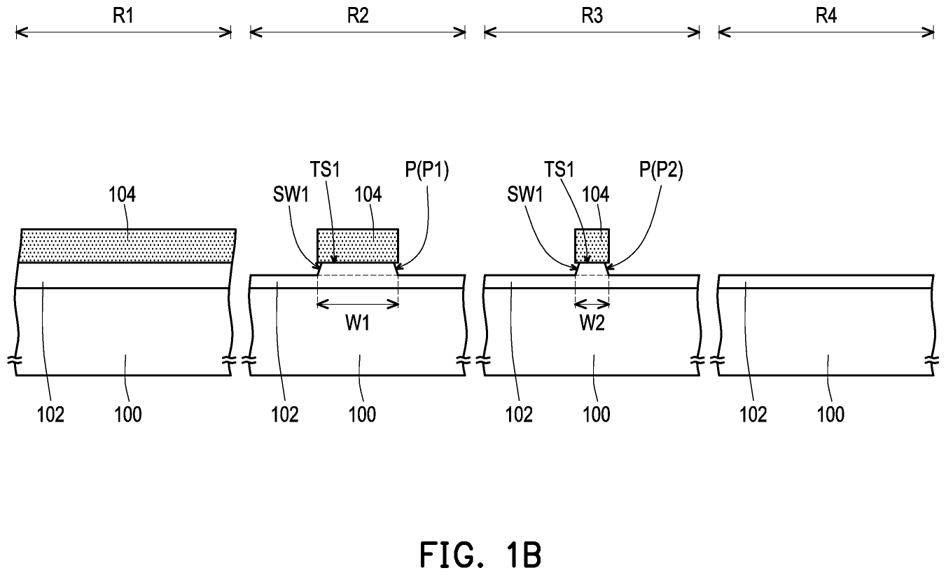

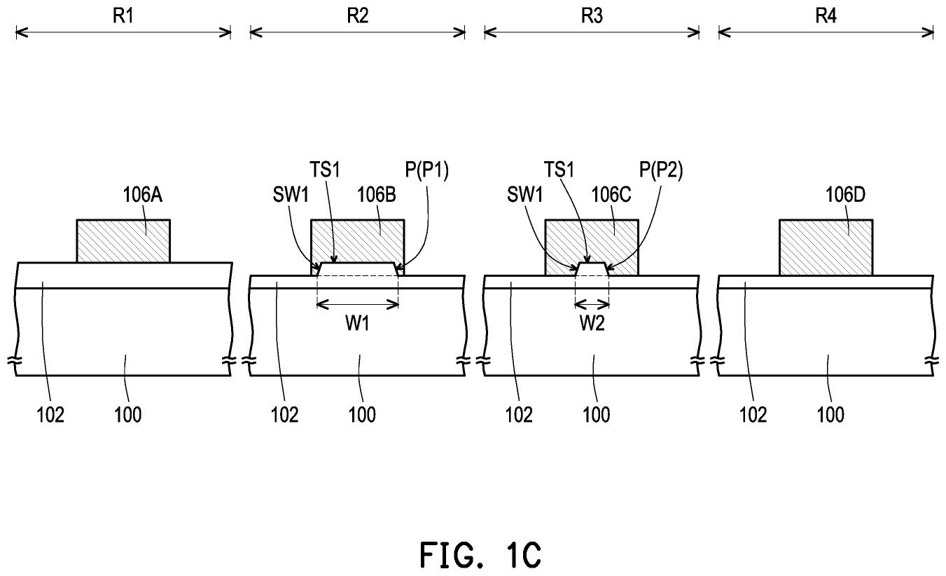

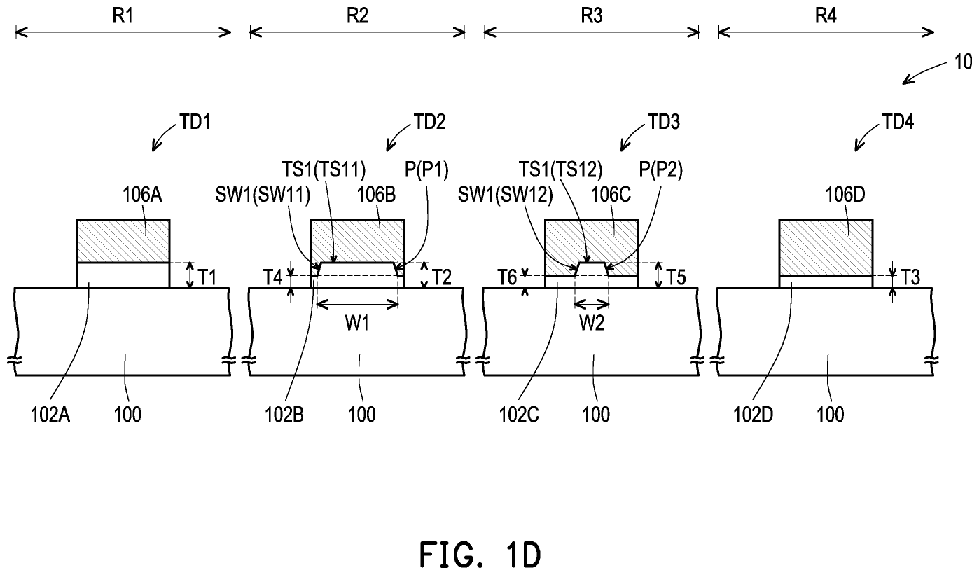

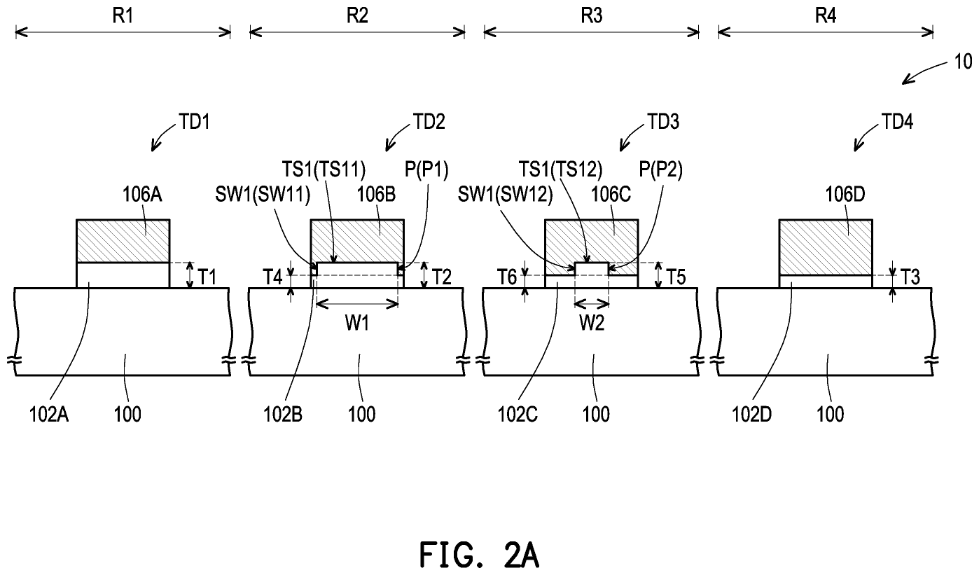

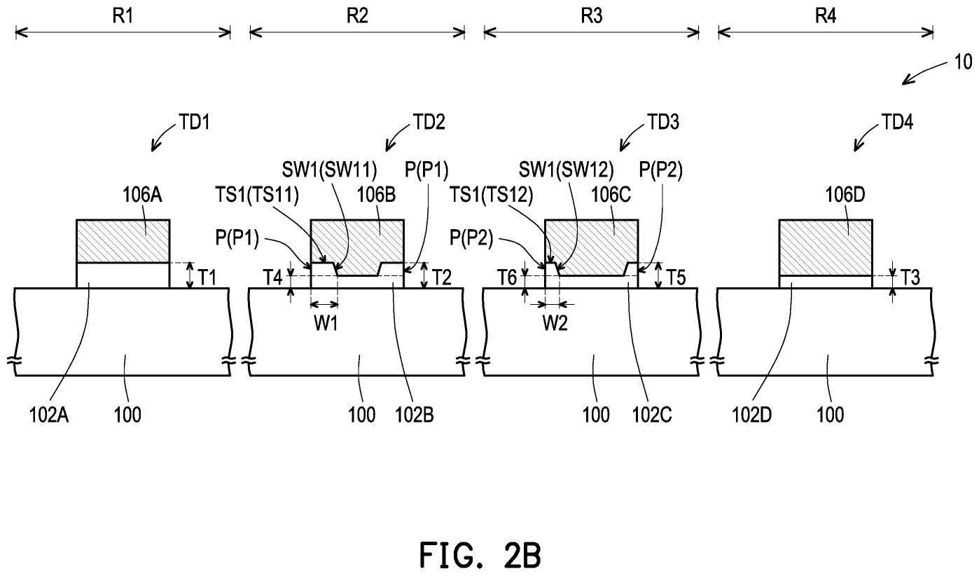

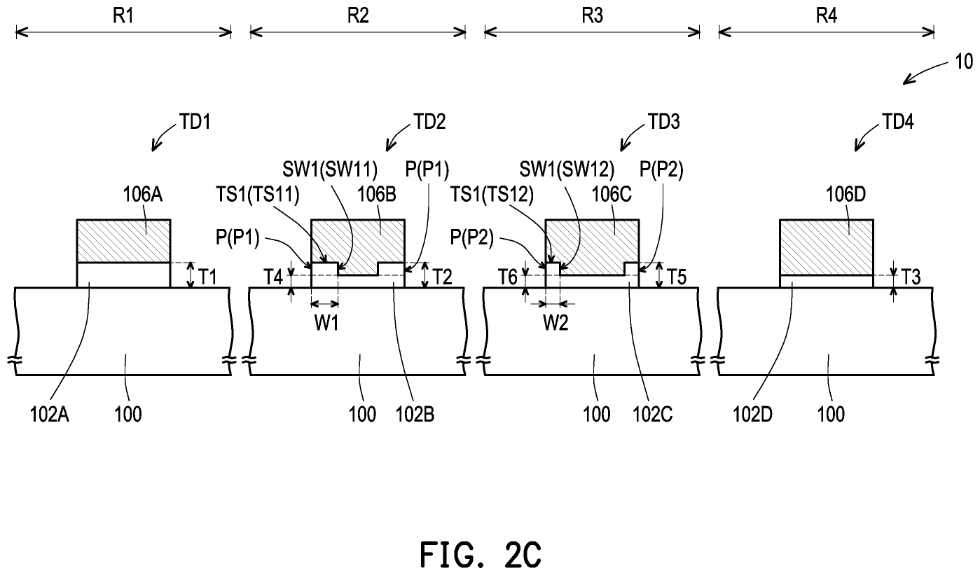

FIG. 1A to FIG. 1D are cross-sectional views of the manufacturing process of a transistor structure according to some embodiments of the invention. FIG. 2A to FIG. 2C are cross-sectional views of the manufacturing process of a transistor structure according to some other embodiments of the invention.

Referring to FIG. 1A, a substrate 100 is provided. The substrate 100 may be a semiconductor substrate, such as a silicon substrate. The substrate 100 may include a first region R1 and a second region R2. In some embodiments, the substrate 100 may further include at least one of a third region R3 and a fourth region R4.

Next, a gate dielectric material layer 102 is formed on the substrate 100. The material of the gate dielectric material layer 102 is, for example, silicon oxide. The forming method of the gate dielectric material layer 102 is, for example, a thermal oxidation method.

Next, a patterned photoresist layer 104 is formed on the gate dielectric material layer 102. The patterned photoresist layer 104 exposes a portion of the gate dielectric material layer 102. In some embodiments, the patterned photoresist layer 104 may completely cover the gate dielectric material layer 102 in the first region R1, the patterned photoresist layer 104 may expose a portion of the gate dielectric material layer 102 in the second region R2 and the third region R3, and the patterned photoresist layer 104 does not cover the gate dielectric material layer 102 in the fourth region R4. The patterned photoresist layer 104 may be formed by a lithography process.

Referring to FIG. 1B, the height of a portion of the gate dielectric material layer 102 exposed by the patterned photoresist layer 104 is reduced, so that the gate dielectric material layer 102 may have at least one protruding portion P. The protruding portion P may have a top surface TS1 and a sidewall SW1. The sidewall SW1 may be connected to the top surface TS1. In the present embodiment, the gate dielectric material layer 102 is exemplified by having a plurality of protruding portions P, but the invention is not limited thereto. For example, a protruding portion P1 may be located in the second region R2, and a protruding portion P2 may be located in the third region R3. In addition, a width W1 of the protruding portion P1 may be greater than a width W2 of the protruding portion P2. In some embodiments, the extending direction of the width W1 of the protruding portion P1 and the extending direction of the width W2 of the protruding portion P2 may be parallel to the channel length direction or the channel width direction. That is, the protruding portions P (e.g., the protruding portion P1 and the protruding portion P2) may be formed in the channel length direction and/or the channel width direction. In addition, the width W1 of the protruding portion P1 and the width W2 of the protruding portion P2 may be defined by the pattern of the patterned photoresist layer 104.

A method for reducing the height of the portion of the gate dielectric material layer 102 exposed by the patterned photoresist layer 104 is, for example, an etching method. The etching method may be a wet etching method or a dry etching method. In the present embodiment, as shown in FIG. 1B, the height of the portion of the gate dielectric material layer 102 exposed by the patterned photoresist layer 104 is reduced using wet etching. Therefore, the protruding portions P may have an inclined sidewall SW1, that is, the sidewall SW1 may be not perpendicular to the top surface TS1. Furthermore, as shown in FIG. 1B, the cross-sectional shape of the protruding portions P may be a trapezoid. In some other embodiments, as shown in FIG. 2A, when the height of the portion of the gate dielectric material layer 102 exposed by the patterned photoresist layer 104 is reduced using wet etching, the protruding portions P may have a perpendicular sidewall SW1, that is, the sidewall SW1 may be perpendicular to the top surface TS1. Furthermore, as shown in FIG. 2A, the cross-sectional shape of the protruding portions P may be a rectangle.

Referring to FIG. 1C, the patterned photoresist layer 104 is removed. The removal method of the patterned photoresist layer 104 is, for example, dry stripping or wet stripping.

Next, a gate 106A and a gate 106B are formed on the gate dielectric material layer 102. The gate 106A and the gate 106B are in the first region R1 and the second region R2, respectively. In addition, the gate 106B may cover the protruding portion P1. In some embodiments, at least one of a gate 106C and a gate 106D may also be formed on gate dielectric material layer 102. The gate 106C and the gate 106D are in the third region R3 and the fourth region R4, respectively. In addition, the gate 106C may cover the protruding portion P2. The gate 106A, the gate 106B, the gate 106C, and the gate 106D may be separated from one another. The material of the gate 106A, the gate 106B, the gate 106C, and the gate 106D is, for example, doped polysilicon. The forming method of the gate 106A, the gate 106B, the gate 106C, and the gate 106D may include the following steps, but the invention is not limited thereto. First, a gate material layer (not shown) is formed on the gate dielectric material layer 102. Next, the gate material layer may be patterned via a lithography process and an etching process to form the gate 106A, the gate 106B, the gate 106C, and the gate 106D.

Referring to FIG. 1D, the gate dielectric material layer 102 is patterned to form a gate dielectric layer 102A located between the gate 106A and the substrate 100 and a gate dielectric layer 102B located between the gate 106B and the substrate 100. In some embodiments, patterning the gate dielectric material layer 102 may also include forming at least one of a gate dielectric layer 102C located between the gate 106C and the substrate 100 and a gate dielectric layer 102D located between the gate 106D and the substrate 100. The gate dielectric layer 102A, the gate dielectric layer 102B, the gate dielectric layer 102C, and the gate dielectric layer 102D may be separated from one another. In some embodiments, the gate dielectric material layer 102 may be patterned using the gate 106A, the gate 106B, the gate 106C, and the gate 106D as a mask, so as to form the gate dielectric layer 102A, the gate dielectric layer 102B, the gate dielectric layer 102C, and the gate dielectric layer 102D, but the invention is not limited thereto.

The gate dielectric layer 102A has a single thickness. The gate dielectric layer 102B has a plurality of thicknesses. The gate dielectric layer 102C may have a plurality of thicknesses. The gate dielectric layer 102D may have a single thickness. A maximum thickness T1 of the gate dielectric layer 102A may be the same as a maximum thickness T2 of the gate dielectric layer 102B. The maximum thickness T2 of the gate dielectric layer 102B may be greater than a maximum thickness T3 of the gate dielectric layer 102D. A minimum thickness T4 of the gate dielectric layer 102B may be equal to the maximum thickness T3 of the gate dielectric layer 102D. The maximum thickness T1 of the gate dielectric layer 102A may be the same as a maximum thickness T5 of the gate dielectric layer 102C. The maximum thickness T5 of the gate dielectric layer 102C may be greater than the maximum thickness T3 of the gate dielectric layer 102D. A minimum thickness T6 of the gate dielectric layer 102C may be equal to the maximum thickness T3 of the gate dielectric layer 102D. The maximum thickness T2 of the gate dielectric layer 102B may be the same as the maximum thickness T5 of the gate dielectric layer 102C. The minimum thickness T4 of the gate dielectric layer 102B may be equal to the minimum thickness T6 of the gate dielectric layer 102C.

In addition, from the above thickness relationship between the gate dielectric layer 102A, the gate dielectric layer 102B, the gate dielectric layer 102C, and the gate dielectric layer 102D and the width relationship between the protruding portion P1 and the protruding portion P2, it may be known that the equivalent oxide thickness (EOT) of the gate dielectric layer 102A may be greater than the EOT of the gate dielectric layer 102B, the EOT of the gate dielectric layer 102B may be greater than the EOT of the gate dielectric layer 102C, and the EOT of the gate dielectric layer 102C may be greater than the EOT of the gate dielectric layer 102D.

Via the above method, a transistor device TD1, a transistor device TD2, a transistor device TD3, and a transistor device TD4 may be formed in the first region R1, the second region R2, the third region R3, and the fourth region R4, respectively. The transistor device TD1 may include the substrate 100, the gate dielectric layer 102A, and the gate electrode 106A, and the gate dielectric layer 102A is located between the gate 106A and the substrate 100. The transistor device TD2 may include the substrate 100, the gate dielectric layer 102B, and the gate electrode 106B, and the gate dielectric layer 102B is located between the gate 106B and the substrate 100. The transistor device TD3 may include the substrate 100, the gate dielectric layer 102C, and the gate electrode 106C, and the gate dielectric layer 102C is located between the gate 106C and the substrate 100. The transistor device TD4 may include the substrate 100, the gate dielectric layer 102D, and the gate electrode 106D, and the gate dielectric layer 102D is located between the gate 106D and the substrate 100.

Moreover, the transistor device TD1, the transistor device TD2, the transistor device TD3, and the transistor device TD4 may further respectively include other desired components (e.g., source regions, drain regions, and/or lightly-doped drain (LDD) regions), and the description thereof is omitted here.

Based on the above embodiments, it may be known that, in the manufacturing method of the transistor structure 10, the height of the portion of the gate dielectric material layer 102 exposed by the patterned photoresist layer 104 is reduced first, and then the gate dielectric material layer 102 is patterned to form the gate dielectric layer 102A having a single thickness and the gate dielectric layer 102B having a plurality of thicknesses. Since the gate dielectric layer 102A and the gate dielectric layer 102B are formed of the same gate dielectric material layer 102, process complexity may be reduced. Moreover, the patterned photoresist layer 104 may be integrated with the patterned photoresist layers used to manufacture other semiconductor devices, thereby reducing the number of photomasks needed for the manufacturing process. For example, when the patterned photoresist layer 104 is used to define the gate dielectric layer of a medium-voltage transistor device, the patterned photoresist layer 104 may be integrated with the patterned photoresist layer used to define a low-voltage transistor device. Moreover, the gate dielectric layer 102A has a single thickness, and the gate dielectric layer 102B has a plurality of thicknesses, so the gate dielectric layer 102A and the gate dielectric layer 102B may have different EOTs. In addition, since the gate dielectric layer 102B has a plurality of thicknesses, the EOT of the gate dielectric layer 102B may be flexibly adjusted via the plurality of thicknesses of the gate dielectric layer 102B.

Hereinafter, the transistor structure 10 of the above embodiment will be described with reference to FIG. 1D. In addition, although the forming method of the transistor structure 10 is described by taking the above method as an example, the invention is not limited thereto.

Referring to FIG. 1D, the transistor structure 10 includes the substrate 100, the gate 106A, the gate 106B, the gate dielectric layer 102A, and the gate dielectric layer 102B. The gate 106A and the gate 106B are located on the substrate 100. The gate dielectric layer 102A is located between the gate 106A and the substrate 100. The gate dielectric layer 102A has a single thickness. The gate dielectric layer 102B is located between the gate 106B and the substrate 100. The gate dielectric layer 102B has a plurality of thicknesses. In some embodiments, the transistor structure 10 may also include at least one of the gate 106C, the gate 106D, the gate dielectric layer 102C, and the gate dielectric layer 102D. The gate 106C is located on the substrate 100. The gate dielectric layer 102C is located between the gate 106C and the substrate 100. The gate dielectric layer 102C has a plurality of thicknesses. The gate 106D is located on the substrate 100. The gate dielectric layer 102D is located between the gate 106D and the substrate 100. The gate dielectric layer 102D has a single thickness. The gate 106A, the gate 106B, the gate 106C, and the gate 106D may be separated from one another. The gate dielectric layer 102A, the gate dielectric layer 102B, the gate dielectric layer 102C, and the gate dielectric layer 102D may be separated from one another.

The maximum thickness T1 of the gate dielectric layer 102A is the same as the maximum thickness T2 of the gate dielectric layer 102B. The maximum thickness T2 of the gate dielectric layer 102B may be greater than the maximum thickness T3 of the gate dielectric layer 102D. The minimum thickness T4 of the gate dielectric layer 102B may be equal to the maximum thickness T3 of the gate dielectric layer 102D. The maximum thickness T1 of the gate dielectric layer 102A may be the same as the maximum thickness T5 of the gate dielectric layer 102C. The maximum thickness T5 of the gate dielectric layer 102C may be greater than the maximum thickness T3 of the gate dielectric layer 102D. The minimum thickness T6 of the gate dielectric layer 102C may be equal to the maximum thickness T3 of the gate dielectric layer 102D. The maximum thickness T2 of the gate dielectric layer 102B may be the same as the maximum thickness T5 of the gate dielectric layer 102C. The minimum thickness T4 of the gate dielectric layer 102B may be equal to the minimum thickness T6 of the gate dielectric layer 102C.

In addition, the gate dielectric layer 102B may include at least one protruding portion P1. The protruding portion P1 may have a top surface TS11 and a sidewall SW11. The sidewall SW11 may be connected to the top surface TS11. In the present embodiment, the sidewall SW11 may be not perpendicular to the top surface TS11, but the invention is not limited thereto. In some other embodiments, as shown in FIG. 2A, the sidewall SW11 may be perpendicular to the top surface TS11.

In addition, the gate dielectric layer 102C may include at least one protruding portion P2. The protruding portion P2 may have a top surface TS12 and a sidewall SW12. The sidewall SW12 may be connected to the top surface TS12. In the present embodiment, the sidewall SW12 may be not perpendicular to the top surface TS12, but the invention is not limited thereto. In some other embodiments, as shown in FIG. 2A, the sidewall SW12 may be perpendicular to the top surface TS12.

In the present embodiment, as shown in FIG. 1D, the gate dielectric layer 102B may include one protruding portion P1, and the gate dielectric layer 102C may include one protruding portion P2, but the invention is not limited thereto. In some other embodiments, as shown in FIG. 2B, the gate dielectric layer 102B may include a plurality of protruding portions P1, and the gate dielectric layer 102C may include a plurality of protruding portions P2, but the number of the protruding portions P1 and the number of the protruding portions P2 are not limited to those shown in FIG. 2B. The number and arrangement of the protruding portions P1 and the number and arrangement of the protruding portions P2 may be adjusted respectively by patterning the pattern of the photoresist layer 104 (FIG. 1A and FIG. 1B). Any number of the protruding portions P1 and any number of the protruding portions P2 of at least one are within the scope of the invention.

Moreover, in the embodiment of FIG. 2B, when the protruding portions P1 and the protruding portions P2 are formed using a wet etching method, the protruding portions P1 may have an inclined sidewall SW11, and the protruding portions P2 may have an inclined sidewall SW12. That is, the sidewall SW11 may be not perpendicular to the top surface TS11, and the sidewall SW12 may be not perpendicular to the top surface TS12, but the invention is not limited thereto. Furthermore, as shown in FIG. 2B, the cross-sectional shape of the protruding portion P1 and the protruding portion P2 may be a trapezoid.

In some other embodiments, as shown in FIG. 2C, when the protruding portions P1 and the protruding portions P2 are formed using a dry etching method, the protruding portions P1 may have a perpendicular sidewall SW11, and the protruding portions P2 may have a perpendicular sidewall SW12. That is, the sidewall SW11 may be perpendicular to the top surface TS11, and the sidewall SW12 may be perpendicular to the top surface TS12. Furthermore, as shown in FIG. 2C, the cross-sectional shape of the protruding portion P1 and the protruding portion P2 may be a rectangle.

In addition, the details of the components in the transistor structure 10 (e.g., materials, configuration relationships, forming methods, and functions, etc.) are described in detail in the above embodiments, and will not be described herein again.

It may be known from the above embodiments that, in the transistor structure 10, the gate dielectric layer 102A has a single thickness, the gate dielectric layer 102B has a plurality of thicknesses, and the maximum thickness of the gate dielectric layer 102A is the same as the maximum thickness of the gate dielectric layer 102B. Therefore, the EOT of the gate dielectric layer 102A may be greater than the EOT of the gate dielectric layer 102B. In addition, since the gate dielectric layer 102B has a plurality of thicknesses, the EOT of the gate dielectric layer 102B may be flexibly adjusted via the plurality of thicknesses of the gate dielectric layer 102B. Moreover, the maximum thickness of the gate dielectric layer 102A is the same as the maximum thickness of the gate dielectric layer 102B. Therefore, the gate dielectric layer 102A and the gate dielectric layer 102B may be formed from the same gate dielectric material layer 102, thereby reducing process complexity.

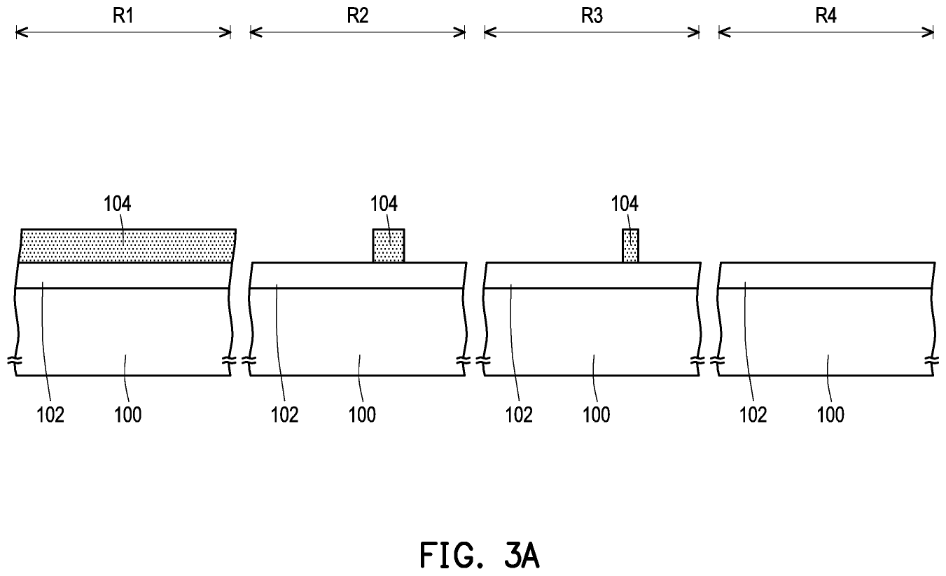

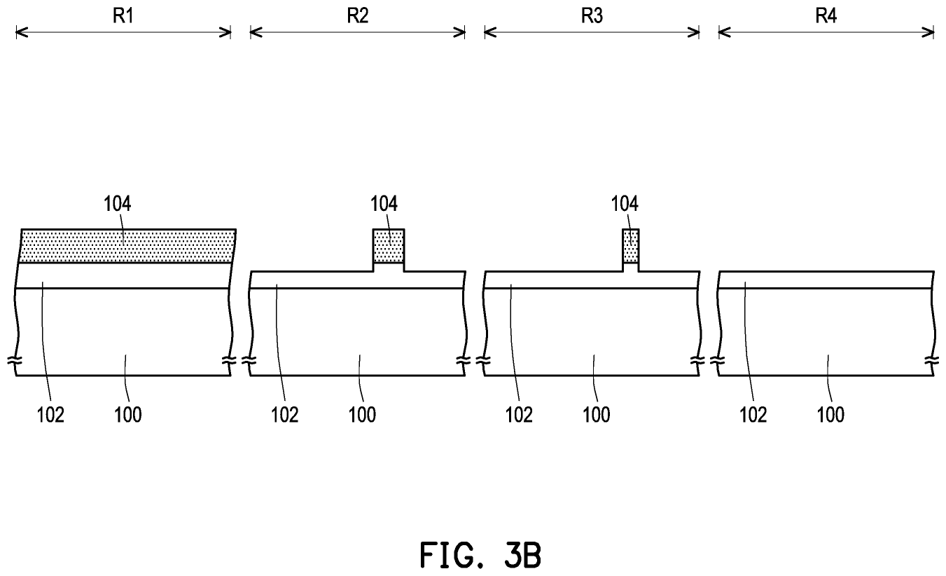

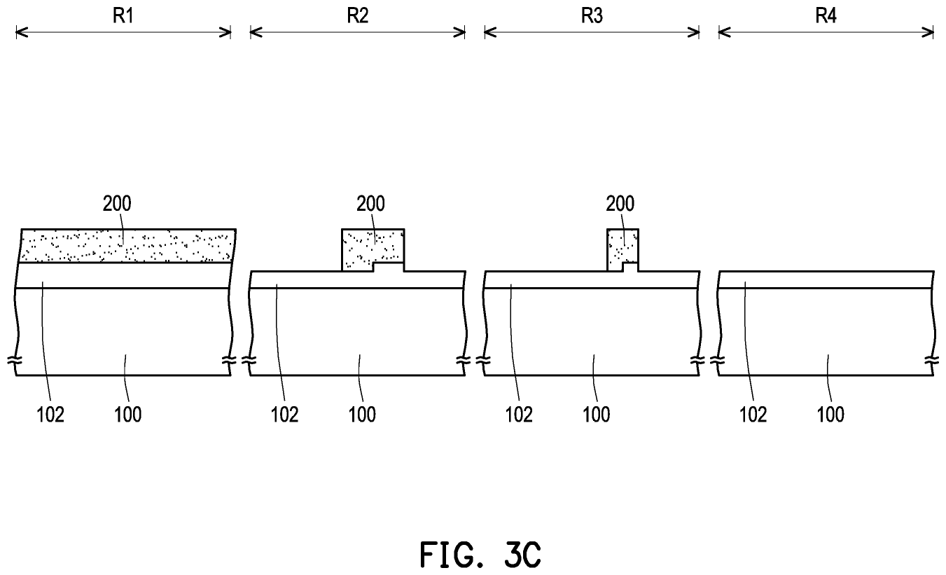

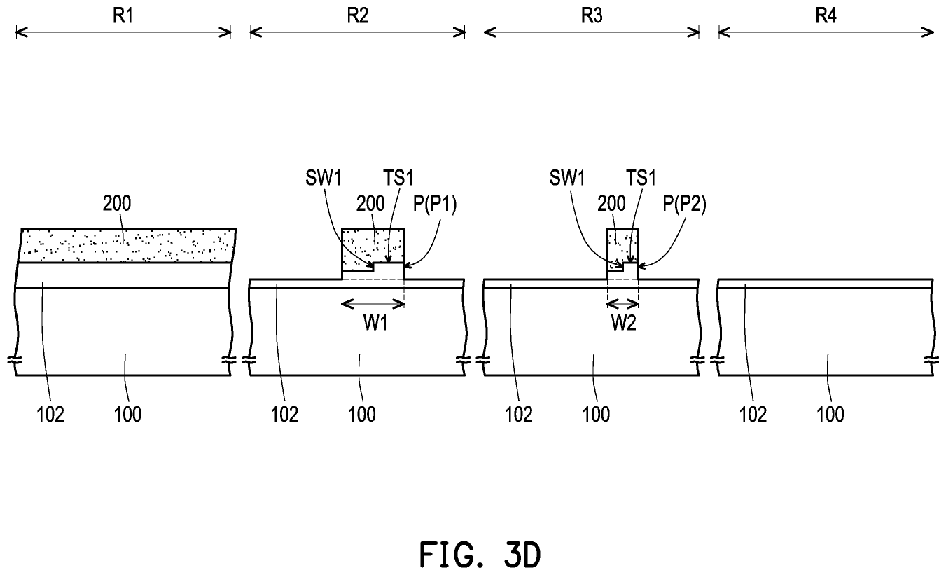

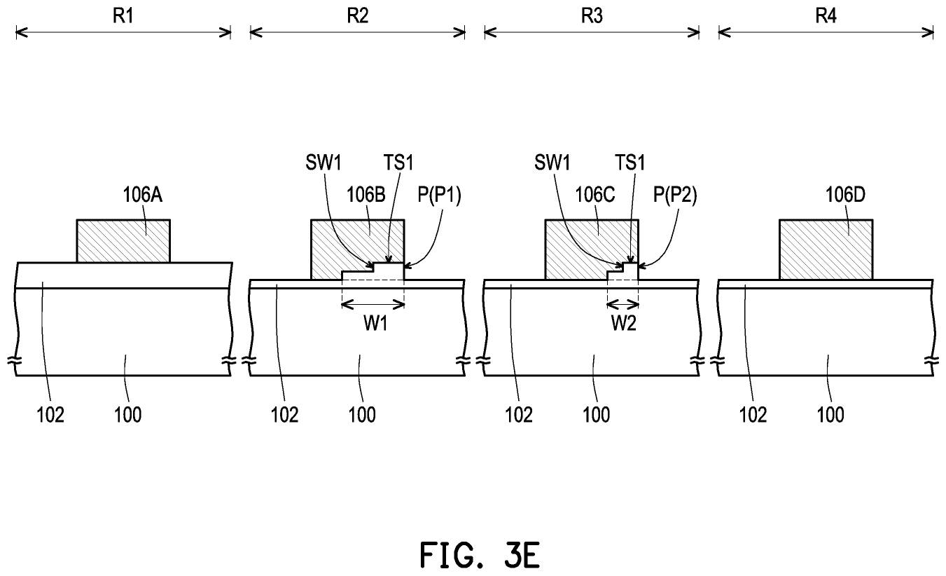

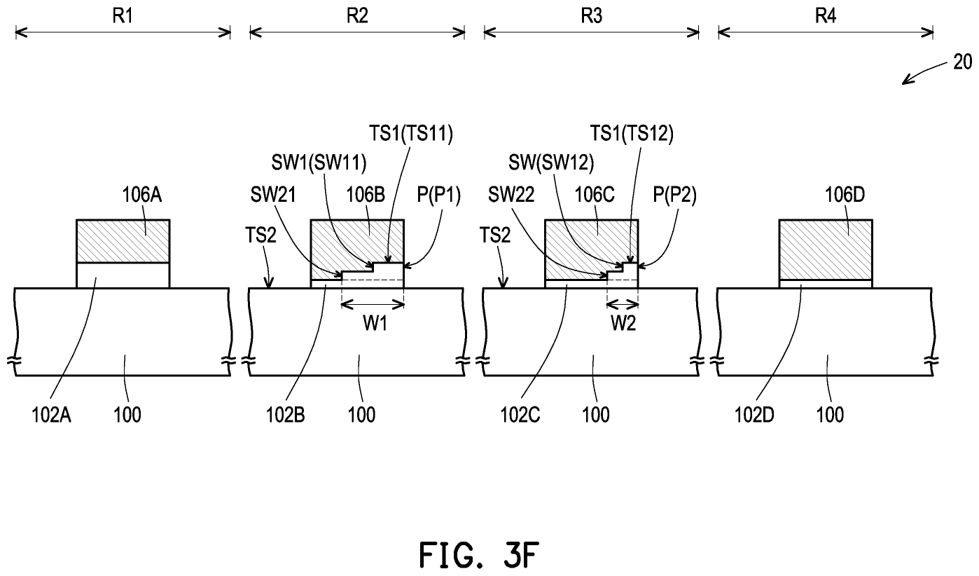

FIG. 3A to FIG. 3F are cross-sectional views of the manufacturing process of a transistor structure according to some other embodiments of the invention.

Referring to FIG. 1A to FIG. 1D and FIG. 3A to FIG. 3F, the differences in structure and manufacturing method between a transistor structure 20 of FIG. 3F and the transistor structure 10 of FIG. 1D are as follows. Referring to FIG. 3C, after the patterned photoresist layer 104 is removed, a patterned photoresist layer 200 is formed on the gate dielectric material layer 102. The patterned photoresist layer 200 exposes a portion of the gate dielectric material layer 102. In some embodiments, the patterned photoresist layer 200 may completely cover the gate dielectric material layer 102 in the first region R1, the patterned photoresist layer 200 may expose a portion of the gate dielectric material layer 102 in the second region R2 and the third region R3, and the patterned photoresist layer 200 does not cover the gate dielectric material layer 102 in the fourth region R. The patterned photoresist layer 200 may be formed by a lithography process. Referring to FIG. 3D, the height of a portion of the gate dielectric material layer 102 exposed by the patterned photoresist layer 200 is reduced, so that the gate dielectric material layer 102 may have at least one protruding portion P (such as the protruding portion P1 and the protruding portion P2). Referring to FIG. 3E, the patterned photoresist layer 200 is removed. In addition, the remaining steps in the manufacturing method of the transistor structure 20 are as provided in the description of FIG. 1A to FIG. 1D, and will not be described herein again.

Referring to FIG. 3F, in the transistor structure 20, the cross-sectional shape of the protruding portion P1 and the cross-sectional shape of the protruding portion P2 may be stepped, respectively. In the present embodiment, as shown in FIG. 3F, the protruding portion P1 may have vertical sidewall SW11 and SW21, and the protruding portion P2 may have vertical sidewalls SW12 and SW22. That is, as shown in FIG. 3F, the sidewall SW11 may be perpendicular to the top surface TS11, the sidewall SW12 may be perpendicular to the top surface TS12, the sidewall SW21 may be perpendicular to the top surface TS2 of the substrate 100, and the sidewall SW22 may be perpendicular to the top surface TS2 of the substrate 100, but the invention is not limited thereto. In some other embodiments, the sidewall SW11 may be not perpendicular to the top surface TS11. In some other embodiments, the sidewall SW12 may be not perpendicular to the top surface TS12. In other embodiments, the sidewall SW21 may be not perpendicular to the top surface TS2 of the substrate 100. In other embodiments, the sidewall SW22 may be not perpendicular to the top surface TS2 of the substrate 100.

Moreover, in the transistor structure 10 of FIG. 1D and the transistor structure of FIG. 3F, the same or similar components are denoted by the same or similar reference numerals, and the description thereof is omitted.

Based on the above, the transistor structure and the manufacturing method thereof of the above embodiments may flexibly adjust the EOT of the gate dielectric layer, so as to manufacture transistor devices having different electrical properties. In addition, the transistor structure and the manufacturing method thereof of the above embodiments may reduce process complexity.

Although the invention is disclosed as above by the embodiments, the embodiments are not intended to limit the invention. Any person skilled in the art may make some changes and modifications without departing from the spirit and scope of the invention. Therefore, the scope of the invention shall be subject to what is defined in the claims.

What is claimed is:

1. A transistor structure, comprising:
a substrate;
a first gate and a second gate located on the substrate;
a first gate dielectric layer located between the first gate and the substrate and having a single thickness; and
a second gate dielectric layer located between the second gate and the substrate and having a plurality of thicknesses, wherein
a maximum thickness of the first gate dielectric layer is the same as a maximum thickness of the second gate dielectric layer.

2. The transistor structure of claim 1, wherein the second gate dielectric layer comprises at least one protruding portion.

3. The transistor structure of claim 1, wherein the protruding portion has a top surface and a sidewall, and the sidewall is connected to the top surface.

4. The transistor structure of claim 3, wherein the sidewall is not perpendicular to the top surface.

5. The transistor structure of claim 3, wherein the sidewall is perpendicular to the top surface.

6. The transistor structure of claim 1, further comprising:
a third gate located on the substrate; and
a third gate dielectric layer located between the third gate and the substrate and having the single thickness.

7. The transistor structure of claim 6, wherein a maximum thickness of the second gate dielectric layer is greater than a maximum thickness of the third gate dielectric layer.

8. The transistor structure of claim 6, wherein a minimum thickness of the second gate dielectric layer is equal to a maximum thickness of the third gate dielectric layer.

9. The transistor structure of claim 1, wherein the first gate and the second gate are separated from each other.

10. The transistor structure of claim 1, wherein the first gate dielectric layer and the second gate dielectric layer are separated from each other.

11. A manufacturing method of a transistor structure, comprising:
providing a substrate;
forming a gate dielectric material layer on the substrate;
forming a first patterned photoresist layer on the gate dielectric material layer, wherein the first patterned photoresist layer exposes a portion of the gate dielectric material layer;
reducing a height of the portion of the gate dielectric material layer exposed by the first patterned photoresist layer;
removing the first patterned photoresist layer;
forming a first gate and a second gate on the gate dielectric material layer; and
patterning the gate dielectric material layer to form a first gate dielectric layer located between the first gate and the substrate and a second gate dielectric layer located between the second gate and the substrate, wherein
the first gate dielectric layer has a single thickness, and the second gate dielectric layer has a plurality of thicknesses.

12. The manufacturing method of the transistor structure of claim 11, wherein a maximum thickness of the first gate dielectric layer is equal to a maximum thickness of the second gate dielectric layer.

13. The manufacturing method of the transistor structure of claim 11, further comprising:
forming a third gate on the gate dielectric material layer.

14. The manufacturing method of the transistor structure of claim 13, wherein patterning the gate dielectric material layer further comprises forming a third gate dielectric layer located between the third gate and the substrate, and the third gate dielectric layer has a single thickness.

15. The manufacturing method of the transistor structure of claim 14, wherein a maximum thickness of the second gate dielectric layer is greater than a maximum thickness of the third gate dielectric layer.

16. The manufacturing method of the transistor structure of claim 14, wherein a minimum thickness of the second gate dielectric layer is equal to a maximum thickness of the third gate dielectric layer.

17. The manufacturing method of the transistor structure of claim 11, further comprising:
forming, after the first patterned photoresist layer is removed, a second patterned photoresist layer on the gate dielectric material layer, wherein the second patterned photoresist layer exposes a portion of the gate dielectric material layer; and
reducing a height of the portion of the gate dielectric material layer exposed by the second patterned photoresist layer.

18. The manufacturing method of the transistor structure of claim 11, wherein a method of reducing the height of the portion of the gate dielectric material layer exposed by the first patterned photoresist layer comprises an etching method.

19. The manufacturing method of the transistor structure of claim 18, wherein the etching method comprises a wet etching method.

20. The manufacturing method of the transistor structure of claim 18, wherein the etching method comprises a dry etching method.
